(19) United States
(12) Patent Application Publication
(10) Pub. No.: US 2010/0142581 A1
(43) Pub. Date: Jun. 10, 2010

(54) CONTACT PADS ON ARRAYS OF OPTICAL DEVICES

(75) Inventor: Ian Andrew Baker, South Lanarkshire (GB)

Correspondence Address: Momkus McCluskey, LLC, 1001 Warrenville Road, Suite 500, Lisle, IL, 60532, US

(73) Assignee: INTENSE LIMITED, Glasgow (GB)

(21) Appl. No.: 12/531,194

(22) PCT Filed: Mar. 17, 2008
(86) PCT No.: PCT/GB2008/000932

§ 371 Date: Jan. 19, 2010

(30) Foreign Application Priority Data
Mar. 15, 2007 (GB) 0704944.8

(51) Int. Cl. H01S 5/40

(52) U.S. Cl. 372/50.123

(57) ABSTRACT

A monolithic laser array (30) has a plurality of parallel laser elements (31-1, 31-2 . . . 31-16) configured such that there is significantly reduced bond pad metallization area and drive contact metallization area between adjacent pairs of laser elements. Each laser element has a waveguide (33) extending along its optical axis, a drive contact (34) extending along at least a portion of the waveguide (33), and a bond pad area (35) extending laterally from the drive contact. The laser elements are arranged in pairs of adjacent laser elements with each laser element of a pair having its bond pad area (35) extending laterally towards the other laser element of the pair and occupying a respective portion of the substrate surface between the laser elements of the pair. The substrate surface between pairs of laser elements is thereby substantially free of bond pad metallization to form an enhanced cleave area extending over the length of the array.

The present invention relates to monolithic arrays of semiconductor optical devices, such as arrays of semiconductor lasers fabricated on single substrates.

There are a large number of applications for monolithic arrays of semiconductor lasers, for example for use in telecommunications systems, medical applications, laser cutting or welding systems or for use in print heads using optical energy to activate print or other media.

Typically, such semiconductor laser arrays are formed with arrays of parallel laser elements on a single monolithic substrate, each laser element being capable of generating a separately controllable output. In many cases, this means that each laser element must have separate drive contacts and associated bond pads to which an external wire bond can be made in order that each laser element can be independently controlled.

It is desirable that the bond pads provide good electrical communication with their respective drive contacts, and it is also desirable that the electrical characteristics of this electrical communication are as consistent as possible across all laser elements in the array. It is also desirable that the metallization layers used to form the bond pads, the drive contacts and the connections therebetween have as little impact as possible on the ability to cleave the arrays of laser elements in optimum positions.

It is an object of the present invention to offer improvements in some or all of the above aspects.

According to another aspect, the present invention provides a monolithic laser array comprising:
a plurality of laser elements being configured for producing multiple parallel output beams,
each laser element having a waveguide extending along its optical axis, a drive contact extending along at least a portion of the waveguide, and a bond pad area extending laterally from the drive contact,
at least some of the laser elements being arranged in pairs of adjacent laser elements with each laser element of a pair having its bond pad area extending laterally towards the other laser element of the pair and occupying a respective portion of the substrate surface between the laser elements of the pair,
the substrate surface between the pairs of laser elements being substantially free of bond pad metallisation to form an enhanced cleave area extending over the length of the array.

Embodiments of the present invention will now be described by way of example and with reference to the accompanying drawings in which:

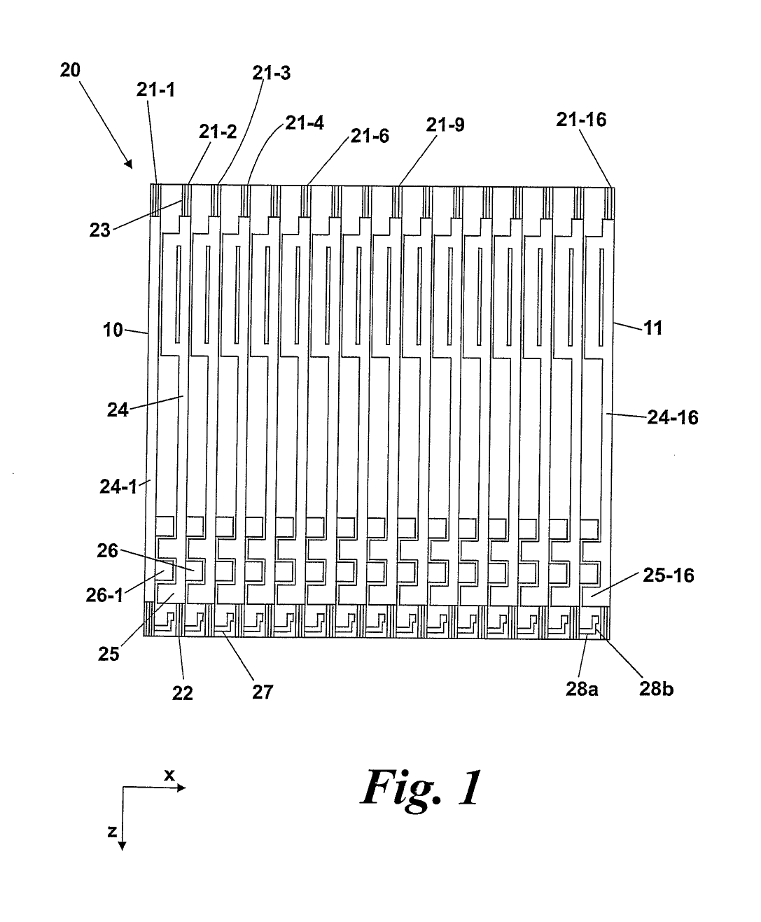

FIG. 1 is a schematic plan view of a prior art monolithic laser array showing a first configuration of bond pads suitable for making electrical connection to the laser elements in the array;

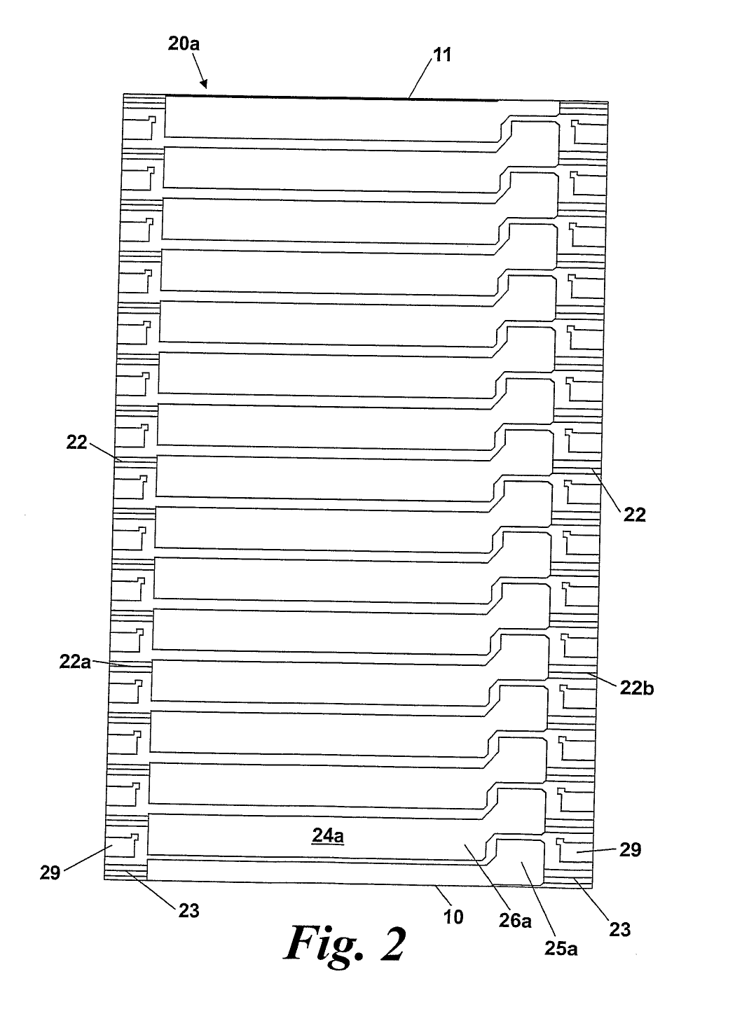

FIG. 2 is a schematic plan view of a prior art monolithic laser array showing a second configuration of bond pads suitable for making electrical connection to the laser elements in the array;

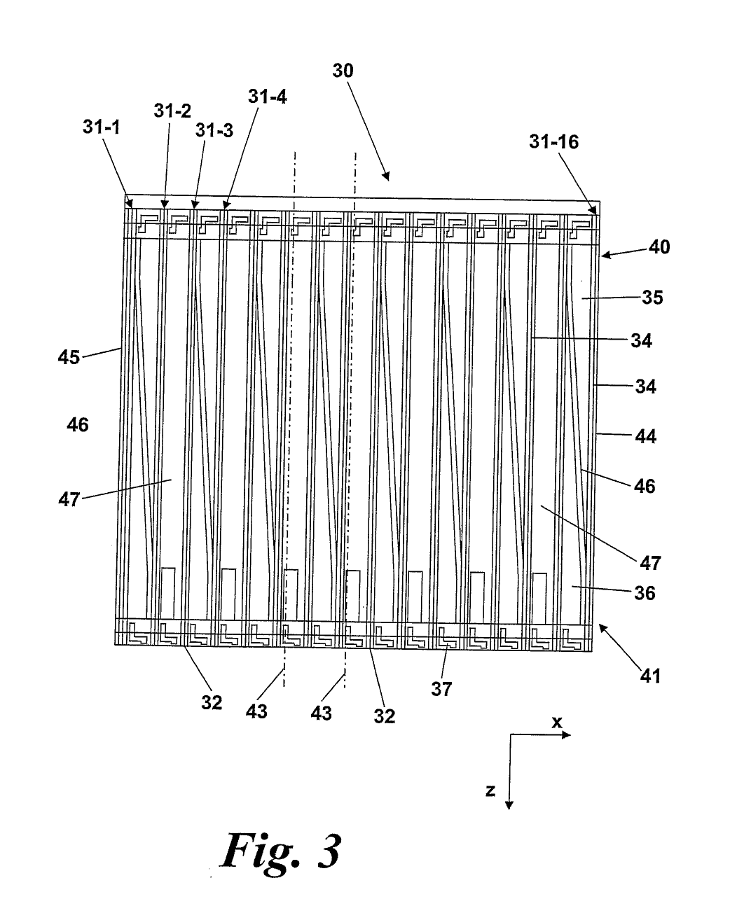

FIG. 3 is a schematic plan view of a monolithic laser array showing a layout which facilitates good cleave conditions between adjacent pairs of laser elements in the array; and

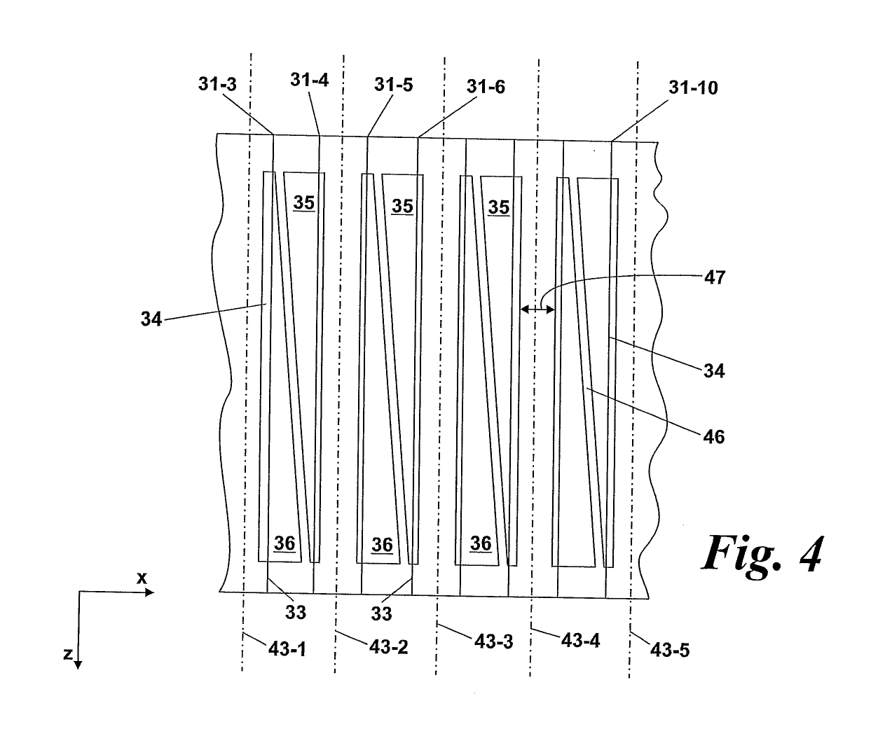

FIG. 4 is a schematic plan view of a part of the array of FIG. 3, significantly expanded on the lateral (x) axis for clarity.

The present specification generally refers to arrays of ‘semiconductor lasers’ or ‘laser elements’. It is intended that these expressions also encompass any other semiconductor optical devices that can generate a coherent or non-coherent optical output from a facet thereof and which are suitable for formation in monolithic arrays of devices.

In many applications, it is necessary to provide a large number of parallel lasers in an array. In a single monolithic laser array, it may be disadvantageous to fabricate more than a few tens of lasers on each substrate for several reasons.

Firstly, the yield falls with increasing number of laser elements, making large arrays significantly more expensive. Secondly, the larger the array, the greater the difficulties in maintaining consistent output performance from each laser in the array, e.g. because of temperature profiles across the array.

Thus, it is often preferred to fabricate smaller arrays (e.g. of sixteen laser elements) and then to mount multiple arrays onto a single carrier. This presents a number of problems relating to alignment of the arrays so that the laser optical outputs from adjacent arrays are very precisely positioned relative to one another. This is important, particularly though not exclusively, in printing applications where the laser element output beams are used to create visible markings on print media, because the human eye is very sensitive to small irregularities in the spacing of dots in an otherwise regular array of dots. Thus, individual arrays of lasers must be precisely registered to one another.

With reference to FIG. 1, there is shown a monolithic semiconductor laser array 20, each array 20 comprising sixteen laser elements 21-1, 21-2 . . . 21-16 each having an optical output facet 22 such that sixteen parallel output beams may be provided. Each laser element 21 comprises an optical waveguide 23, only the passive portion of which is visible at the ends of the device, the active portion being concealed beneath a layer of metallization 24 which forms the drive contact for the laser. The waveguide 23 may be a ridge waveguide in which case the drive contact extends along the ridge (e.g. as shown in the narrow portion of metallization at 24).

The drive contact metallization 24 (i.e. that portion which extends over an active portion of the optical waveguide 23) is electrically connected to, by continuous metallization, a first bond pad area 25 off-waveguide and located near one edge of the array. The first bond pad area is for making wire bond attachments in accordance with normal wire bond techniques. A second bond pad area 26 is included off-waveguide but on the opposite side of the waveguide 23 to the first bond pad area 25. It will be noted that the second bond pad area 26 of the laser element 21-2 effectively encroaches onto the rectangular semiconductor area otherwise occupied by the adjacent laser element 21-3.

Each laser element also includes an alignment fiducial 27 disposed proximal to the output end of the laser element 21 which includes a visible alignment edge in two orthogonal directions, to enable accurate positioning of the laser element and array relative to other components on a substrate or other optical system.

The point of the first and second bond pad areas 25, 26 for each laser 21 is to facilitate cleave of the substrate on which the laser elements 21 are formed at a position very close to the axis of optical waveguide 23 at both lateral edges 10, 11 of the array. This means that the right-most laser element 21-16 at the right hand lateral edge 11 maintains a complete contact metallization area 24-16 leading to a useable first bond pad area 25-16. Note that the second bond pad area 26 for that laser element 21-16 has been lost in the cleave.

Looking at the left hand lateral edge 10 of the array, it can be seen that the left-most laser element 21-1 at the left hand lateral edge 10 maintains a complete contact metallization area 24-1 leading to a useable second bond pad area 26-1. Note that the first bond pad area 25 for that laser element has been lost in the cleave.

This configuration enables the cleave to be as close as possible to the laser waveguide axis at both lateral edges 10, 11 of the array so that adjacent arrays can be mounted very close to one another, thereby maintaining laser element spacing both intra- and inter-array. In other words, the pitch between laser elements can be maintained constant across multiple monolithic arrays.

FIG. 2 illustrates another prior art alternative, on the same principle as FIG. 1, showing a laser array 20a in which the second bond pad areas 26a are extended along a substantial length of the optical axis so that the second bond pad areas 26a are contiguous with a substantial length of the drive contact 24a. Each first bond pad area 25a extends laterally from the other side of each waveguide 23 over a much smaller portion of the length of the waveguide at one end of each laser element.

Thus, it can be seen that the principal feature of the laser arrays of FIGS. 1 and 2 is that each laser element in the array has a bond pad area 25, 25a, 26, 26a extending laterally from both sides of the waveguide 23 so that laser elements 21 at each extreme lateral edge 10, 11 of the array always have a bond pad available for electrical connection to the contact metallization area.

There can be potential disadvantages with both of these approaches.

Firstly, the extent of electrical communication between the bond pad area 25, 25a, 26, 26a and the drive contact metallization region 24, 24a may be somewhat variable depending on whether the first or second bond pad area is used for any given laser element 21. This can give rise to slight variations in electrical performance of lasers across the array, e.g. arising from different capacitance and electrical resistance.

Secondly, particularly in the case of FIG. 2, and to a lesser extent in the case of FIG. 1, cleave has to take place through a substantial area of metallization. It has been found that attempting the scribe and cleave process through such a layer of metallization (e.g. gold) can lead to cleaving defects, inconsistent cleaving quality and damage due to the extra pressure required to complete the scribe and/or cleave process.

With reference to FIG. 3, there is shown an arrangement of drive contact and bond pad metallization which eliminates the need to scribe and cleave through a layer of metallization and which facilitates a clean scribe process through closely packed semiconductor laser arrays.

A monolithic semiconductor laser array 30 comprises sixteen laser elements 31-1, 31-2 . . . 31-16 each having an optical output facet 32 such that sixteen parallel output beams may be provided. Each laser element 31 comprises an optical waveguide 33 extending along the optical axis of the laser, only the passive portion of which is visible, the active portion being concealed beneath a layer of metallization 34 which forms the drive contact for the laser. The waveguide 33 may be a ridge waveguide in which case the drive contact metallization 34 extends over and along the ridge, creating a visible profile in the metallization as shown in FIG. 3.

The drive contact 34 may extend substantially along the entire length of the waveguide (as shown) or may extend only partly along the length of the waveguide, i.e. over one or more portions of the waveguide.

In every second one of the laser elements (i.e. even numbered elements 31-2, 31-4, . . . 31-16), the drive contact metallization 34 (i.e. that portion which extends over an active portion of the optical waveguide 33) is electrically connected, by contiguous metallization, to bond pad areas 35 off-waveguide and extending laterally away from their respective waveguides 33 on the left hand side as shown in FIG. 3. These bond pad areas 35 are for making wire bond attachments in accordance with normal wire bond techniques at any suitable location thereon, and preferably in the wider portions at the first ends 40 of the laser elements 31. These may be called ‘left-handed bond pads’ 35.

In the other laser elements (i.e. odd numbered elements 31-1, 31-3, . . . 31-15), the drive contact metallization 34 is electrically connected, by contiguous metallization, to bond pad areas 36 off-waveguide and extending laterally away from their respective waveguides 33 on the right hand side as shown in FIG. 3. These bond pad areas 36 are also for making wire bond attachments in accordance with normal wire bond techniques at any suitable location thereon, and preferably in the wider portions at the second ends 41 of the laser elements 31. These may be called ‘right-handed bond pads’ 36.

Thus, it will be seen that the laser elements 31 are arranged in pairs of adjacent laser elements (e.g. 31-3, 31-4) with each laser element of a pair having its bond pad area 35 or 36 extending laterally towards the other laser element of the pair and occupying a respective portion of the substrate surface 46 between the laser elements of the pair. The substrate surface 47 between pairs of laser elements is substantially free of bond pad metallization to form an enhanced cleave area extending over the length of the array between the first end 40 and the second end 41 of the array in the direction of the optical axes (z-direction).

In common with the array shown in FIG. 1, each laser element 31 may also include an alignment fiducial 37 disposed proximal to the second end of the laser element 31 which includes a visible alignment edge in two orthogonal directions, to enable accurate positioning of the laser element and array relative to other components on a substrate or other optical system.

FIG. 4 shows a close-up plan view of a part of the array of FIG. 3 with the lateral (x-axis) significantly expanded for clarity. Adjacent pairs of laser elements 31-3, 31-4, 31-5, . . . 31-10 are visible. Here it can be seen that it is possible to cleave the substrate on which the laser elements 31 are formed at any one of cleave lines 43-1, 43-2, . . . 43-5 in a position very close to the optical waveguide 33 of the laser elements 31 on either side of the cleave line without disrupting the bond pad availability for the laser elements on both sides of the cleave line. This ensures that cleaved laser arrays can be mounted on a suitable package substrate sufficient close to one another that there is little or no disruption to the laser element spacing across multiple arrays.

Like with the arrangements of FIGS. 1 and 2, this configuration enables the cleave to be as close as possible to the laser waveguide axis at both lateral edges 44, 45 of the array 30 so that adjacent arrays can be mounted very close to one another, thereby maintaining laser element spacing both intra- and inter-array. In other words, the pitch between laser elements can be maintained constant across multiple monolithic arrays. The cleave line 43 can be targeted exactly half way between laser elements, e.g. cleave line 43-2 lies exactly between laser elements 31-4 and 31-5.

It also ensures that a bond pad area 35 or 36 is available for each laser element even at the extreme lateral edges 44, 45 (FIG. 3) of the cleaved array.

It will be seen that, although the arrays can now only be cleaved between alternate pairs of adjacent laser elements, the benefit of this slight restriction on cleave position is that the cleave can take place without dissecting any metallized area of bond pad 35, 36 or drive contact 34, avoiding the problems associated therewith discussed above.

Furthermore, it can be seen that the electrical characteristics of the connection between bond pad areas 35, 36 and respective drive contact areas 34 (which are preferably contiguous along the entire length of the drive contact, as shown) are the same for left-handed bond pads 35 and for right-handed bond pads 36.

A significant number of modifications and variations can be made to the arrangements of FIGS. 3 and 4. It will be recognised that the drive contact area 34 and associated bond pad area 35 or 36 need not necessarily be triangular in shape as shown. More generally, the bond pad area shapes for each adjacent laser element pair (e.g. 31-5, 31-6) need only have complementary shapes so that together they share the substrate surface between the adjacent laser element pairs in a non-overlapping manner.

Preferably, the complementary shapes have the same surface area as each other to enhance electrical similarity (e.g. sheet resistivity, electrical resistance and capacitance). This helps in ensuring an optimum consistency of electrical characteristics for electrical conduction from a wire bond to the drive contact.

More preferably, the two complementary shapes are exactly the same shape as one another but rotated through 180 degrees, i.e. having 180 degree rotational symmetry. By making the two complementary shapes identical to one another in this manner, the electrical similarity of adjacent laser elements in each pair is maximised. However, the complementary shapes need not be identical or even of the same area if sufficient electrical similarity can otherwise be achieved for any given application.

The two complementary shapes can be any suitable shape, including interdigitated structures such as crenellations which offer multiple bond pad positions.

Further, it will be recognised that if complete flexibility in cleave positions across the monolithic array is not required, then only some of the laser elements need be paired in the manner shown in FIGS. 3 and 4. For example, if only arrays of sixteen elements are to be fabricated, then strictly speaking only laser elements 31-1 and 31-2 (or laser elements 31-15 and 31-16) need be paired in the manner shown. If flexibility for cleaving in multiple positions is required, then other laser elements may be selected for the paired configuration. Thus, in a general aspect, at least some or all of the plurality of laser elements are arranged in pairs having the complementary layout described. The remaining (non-paired) laser elements may have bond pad areas that match either the left-handed bond pad 35 configuration, or the right-handed bond pad 36 configuration.

In exemplary configurations for laser print heads, a 125 micron pitch laser element to laser element is sought, and the bond pad areas 35, 36 may be typically up to about 60% of that pitch (e.g. 75 microns wide) adjacent to the drive contact portion which is approximately the width of the waveguide. This allows a width of substrate surface 47 between adjacent pairs of laser elements of approximately 70% of the pitch (e.g. 80 to 100 microns) in which one or more cleaves can take place. Appropriate cutting or lapping of the lateral edges 40, 41 of the cleaved arrays 30 (or, alternatively, performing more than one cleave through the substrate area 47) enables the 125 micron pitch to be easily maintained between adjacent arrays 30 mounted on a common substrate and also allows a useful margin for variability in the cleave process. The spacing between adjacent bond pad areas 35, 36 of a laser element pair can be made very small, e.g. the width of the intra-pair substrate region 46 can be as little as a few microns, and typically 10 to 20% of the laser pitch.

In preferred arrangements, the width of substrate surface between adjacent pairs of lasers which is free of bond pad or drive contact metallization lies between 50 and 90% of the pitch of the laser element spacing. In practice, the width of substrate surface between adjacent pairs of lasers which is free of bond pad or drive contact metallization can be up to 100% of the waveguide-to-waveguide (e.g. ridge-to-ridge) spacing if the drive contact metallization does not extend off or beyond the ridge or buried waveguide.

The laser elements described above are formed using ridge waveguides in which the metallization extends over and off the ridge, but it will be recognised that other types of waveguides such as buried heterostructure waveguides without a ridge may also be used.

As discussed above, the gap between adjacent arrays 30 can be critical in some applications, where any gap which increases the laser pitch between arrays is to be avoided.

Typical thermal printing requirements are for 203 dpi (dots per inch) or 8 dots per mm which means that lasers in the array must be at 125 microns pitch. Other standard pitches are also widely used, such as 250 dpi, 300 dpi, 600 dpi and 1200 dpi. The laser arrays described in connection with FIGS. 3 and 4 can readily be adapted to form monolithic arrays using conventional photolithography processes with these standard laser pitches.

Other embodiments are intentionally within the scope of the accompanying claims.

1. A monolithic laser array comprising:
a plurality of laser elements being configured for producing multiple parallel output beams,
each laser element having a waveguide extending along its optical axis, a drive contact extending along at least a portion of the waveguide, and a bond pad area extending laterally from the drive contact,
at least some of the laser elements being arranged in pairs of adjacent laser elements with each laser element of a pair having its bond pad area extending laterally towards the other laser element of the pair and occupying a respective portion of the substrate surface between the laser elements of the pair,
the substrate surface between the pairs of laser elements being substantially free of bond pad metallisation to form an enhanced cleave area extending over the length of the array.

2. The monolithic laser array of claim 1 in which the bond pad area for each paired laser element is substantially triangular, the two laser elements in each pair having complementary triangular bond pad areas.

3. The monolithic laser array of claim 2 in which the two complementary triangular areas together define a substantially rectangular region extending over and between each pair of laser element waveguides.

4. The monolithic laser array of claim 1 in which the bond pad area for each paired laser element has a shape that is complementary to the bond pad area of the other laser element in its pair.

5. The monolithic laser array of claim 4 in which the bond pad area for each paired laser element has a shape that is substantially the same as that of the other laser element in its pair under 180 degree rotational symmetry.

6. The monolithic laser array of claim 4 in which the two bond pad areas for each pair of laser elements are interdigitated.

7. The monolithic laser array of claim 1 in which the bond pad areas of each paired laser element are substantially equal in area.

8. The monolithic laser array of claim 6 in which the bond pad areas of each paired laser element have substantially the same electrical characteristics for electrical conduction to the drive contact.

9. The monolithic laser array of claim 1 in which all of the laser elements in the monolithic array are arranged in said pairs.

10. A monolithic laser array substantially as described herein with reference to the accompanying drawings.
